(19) United States
(12) Patent Application Publication
(10) Pub. No.: US 2013/0328217 A1
(43) Pub. Date: Dec. 12, 2013

(54) METHOD OF MARKING SEMICONDUCTOR ELEMENT, METHOD OF MANUFACTURING SEMICONDUCTOR DEVICE, AND SEMICONDUCTOR DEVICE

(71) Applicant: NITTO DENKO CORPORATION, Osaka (JP)

(72) Inventors: Naohide TAKAMOTO, Osaka (JP); Goji SHIGA, Osaka (JP)

(21) Appl. No.: 13/910,304

(22) Filed: Jun. 5, 2013

(30) Foreign Application Priority Data
Jun. 7, 2012 (JP) 2012-130036

(51) Int. Cl. H01L 21/56

(52) U.S. Cl. CPC H01L 21/561
USPC 257/778; 438/795; 438/108

(57) ABSTRACT

An object of the present invention is to provide a method of marking a semiconductor element with which a semiconductor device can be manufactured effectively even in the case of marking every semiconductor element, and a method of manufacturing the semiconductor device. The present invention relates to a method of marking a semiconductor element, wherein marking is performed on a semiconductor element that is inserted in a pocket of a carrier that can be wound up in a reel state. The present invention relates to a method of manufacturing a semiconductor device comprising: a step 1 of inserting a semiconductor element in a pocket of a carrier that can be wound up in a reel state; and a step 2 of marking the semiconductor element that is inserted in the pocket.

### BACKGROUND OF THE INVENTION

1. Field of the Invention

The present invention relates to a method of marking a semiconductor element, a method of manufacturing a semiconductor device, and a semiconductor device obtained by the manufacturing method.

2. Description of the Related Art

In recent years, there have been increasing demands for thickness reduction and size reduction of semiconductor devices and packages thereof. Because of that, a flip-chip type semiconductor device has been broadly used in which a semiconductor element is mounted on a substrate by flip-chip bonding (flip-chip connection) as a semiconductor device and a package thereof.

In flip-chip connection, a semiconductor chip is fixed to a substrate in a condition that the circuit surface of the semiconductor chip is opposite to the electrode forming surface of the substrate. There are cases where damages of the semiconductor chip are prevented by protecting the backside of the semiconductor chip with a protective film in such a semiconductor device

However, it is necessary to add a new step of pasting a protecting film to the backside of the semiconductor chip that is obtained in a dicing step to protect the backside of the semiconductor chip with the protecting film. As a result, the number of steps increases and manufacturing cost increases. Against such problems, it has been known to use a dicing-tape integrated film for the backside of a semiconductor to reduce manufacturing cost. The dicing-tape integrated film for the backside of a semiconductor has a structure including a dicing tape having a pressure-sensitive adhesive layer on a base and a film for the backside of a flip-chip semiconductor that is provided on the pressure-sensitive adhesive layer of the dicing tape. The dicing-tape integrated film for the backside of a semiconductor can be used as follows when a semiconductor device is manufactured. First, a semiconductor wafer is pasted to the film for the backside of a flip-chip semiconductor of the dicing-tape integrated film for the backside of a semiconductor. Next, the semiconductor wafer is diced to form a semiconductor chip. The semiconductor chip is picked up together with the film for the backside of a flip-chip semiconductor by peeling it off from the pressure-sensitive adhesive layer of the dicing tape. Then, the semiconductor element obtained from pickup is fixed to an adherend such as a substrate by flip-chip connection. With this connection, a flip-chip semiconductor device is obtained.

Conventionally, various information (character information such as a product number and graphic information such as two-dimensional bar codes for example) is required to be visibly given to (marked) a semiconductor element that is manufactured and a semiconductor device that is manufactured using the semiconductor element for the purpose of product management, etc.

### SUMMARY OF THE INVENTION

However, when the dicing-tape integrated film for the backside of a semiconductor is used, it is difficult to perform marking on every semiconductor wafer due to the existence of the dicing tape. For this reason, when the dicing-tape integrated film for the backside of a semiconductor is used, a step becomes necessary of performing the alignment (aligning the position) of every semiconductor element and then marking, and the productivity (UPH: Utility Per Hour) remarkably decreases as compared with the case of marking every semiconductor wafer.

An object of the present invention is to provide a method of marking a semiconductor element with which a semiconductor device can be manufactured effectively even in the case of marking every semiconductor element, and a method of manufacturing the semiconductor device.

The present inventors have focused on a process of, while sending (winding) a carrier that can be wound up in a reel state to a reel, inserting a semiconductor element in a pocket of the carrier in the manufacturing processes of a semiconductor device. Then, they have found that the object can be achieved by marking the semiconductor element that is inserted in the pocket of the carrier, and completed the present invention.

That is, the present invention relates to a method of marking a semiconductor element, wherein marking is performed on a semiconductor element that is inserted in a pocket of a carrier that can be wound up in a reel state.

According to the above-described configuration, there is no need to provide an independent step for marking. For this reason, a semiconductor device can be effectively manufactured even in the case of marking every semiconductor element.

Further, the alignment (aligning the position) is generally performed before marking. According to the above-described configuration, the positional shift of each semiconductor element is slight and it can be effectively aligned because the semiconductor element is continuously sent to a region where the alignment mark can be detected by the carrier that can be wound up in a reel state. As a result, a semiconductor device can be effectively manufactured.

The marking is preferably a laser marking.

The marking is preferably performed on the backside of the semiconductor element.

The semiconductor element preferably has a film for the backside of a flip-chip semiconductor that is formed on the backside of a semiconductor chip that is flip-chip-connected to an adherend, and

marking is preferably performed on the film for the backside of a flip-chip semiconductor.

The present invention relates to a method of manufacturing a semiconductor device comprising:

a step 1 of inserting a semiconductor element in a pocket of a carrier that can be wound up in a reel state; and

a step 2 of marking the semiconductor element that is inserted in the pocket.

According to the above-described configuration, there is no need to provide an independent step for marking. For this reason, a semiconductor device can be effectively manufactured even in the case of marking every semiconductor element.

Further, the alignment (aligning the position) is generally performed before marking. According to the above-described configuration, the positional shift of each semiconductor element is slight and it can be effectively aligned because the semiconductor element is continuously sent to a region where the alignment mark can be detected by the carrier that can be wound up in a reel state. As a result, a semiconductor device can be effectively manufactured.

The method of manufacturing a semiconductor device preferably comprises:

a step A of laminating a dicing-tape integrated film for the backside of a semiconductor, in which the film for the backside of a flip-chip semiconductor that is formed on the backside of a semiconductor chip that is flip-chip-connected to an adherend is laminated onto a dicing tape, to a semiconductor wafer;

a step B of dicing the semiconductor wafer that is laminated by the film for the backside of a flip-chip semiconductor; and

a step C of picking up the semiconductor chip obtained by dicing together with the film for the backside of a flip-chip semiconductor to obtain the semiconductor element having the film for the backside of a flip-chip semiconductor, wherein

marking is preferably performed in the step 2 on the film for the backside of a flip-chip semiconductor of the semiconductor element that is obtained in the step C.

When the dicing-tape integrated film for the backside of a semiconductor is used, it is necessary to mark every semiconductor element. According to the above-described configuration, a semiconductor device can be effectively manufactured.

The method of manufacturing a semiconductor device preferably comprises a step 3 of sealing the semiconductor element that is marked in the step 2 by pasting a cover tape to the carrier that can be wound up in a reel state.

The semiconductor element preferably has a film for the backside of a flip-chip semiconductor that is formed on the backside of a semiconductor chip that is flip-chip-connected to an adherend, and

the film for the backside of a flip-chip semiconductor is preferably formed of a resin composition containing a thermoplastic resin and/or a thermosetting resin.

The film for the backside of a flip-chip semiconductor is preferably formed of the resin composition containing a thermosetting resin, and

the thermosetting resin is preferably uncured in the step 3.

According to the above-described configuration, the manufacturing steps can be simplified because a step of curing the film for the backside of a flip-chip semiconductor is not included before the step 3. As a result, a semiconductor device can be effectively manufactured.

The present invention relates to a semiconductor device obtained with the manufacturing method.

Various information (such as character information and graphic information) of the semiconductor device that is obtained with the above-described manufacturing method can be visibly recognized well.

According to the method of marking a semiconductor element and method of manufacturing a semiconductor device of the present invention, a semiconductor device can be manufactured effectively even in the case of marking every semiconductor element.

### BRIEF DESCRIPTION OF THE DRAWINGS

FIG. 1 is a schematic sectional view showing how a semiconductor element is inserted in a pocket of a carrier that can be wound up in a reel state;

FIG. 2 is a schematic sectional view showing a dicing-tape integrated film for the backside of a semiconductor that can be used in the present invention;

FIG. 3A to 3C are schematic sectional views showing one example of a method of manufacturing a semiconductor element;

FIG. 4 is a schematic sectional view showing how a semiconductor element is inserted in a pocket of a carrier that can be wound up in a reel state; and

FIG. 5 is a schematic sectional view showing a flip-chip semiconductor device.

### DETAILED DESCRIPTION OF THE PREFERRED EMBODIMENT

In the method of marking a semiconductor element of the present invention, the marking is performed on a semiconductor element that is inserted in a pocket of a carrier that can be wound up in a reel state. The method of manufacturing a semiconductor device of the present invention has a step 1 of inserting a semiconductor element in a pocket of a carrier that can be wound up in a reel state and a step 2 of marking the semiconductor element that is inserted in the pocket.

The method of marking a semiconductor element and method of manufacturing a semiconductor device of the preset invention is explained by referring to the drawings. However, the present invention is not limited to these examples.

In the present specification, parts that are unnecessary for the explanation are omitted in the drawings, and there are parts that are enlarged or shrunk in the drawings to make the explanation easy.

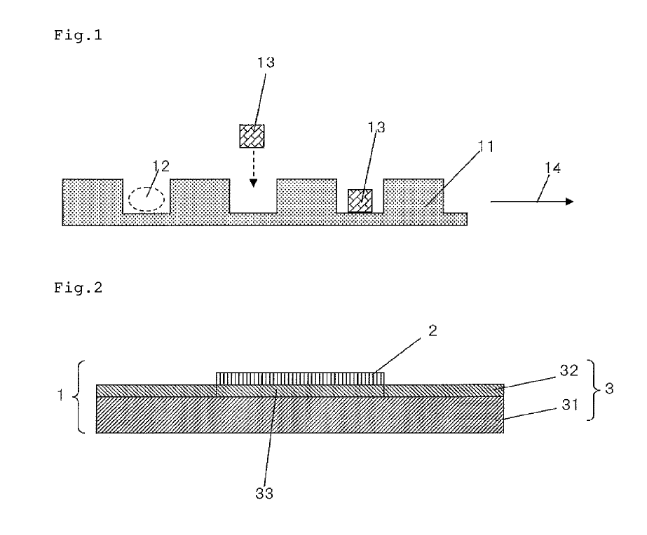

FIG. 1 is a schematic sectional view showing how a semiconductor element is inserted in a pocket of a carrier that can be wound up in a reel state.

FIG. 2 is a schematic sectional view showing a dicing-tape integrated film for the backside of a semiconductor that can be used in the present invention.

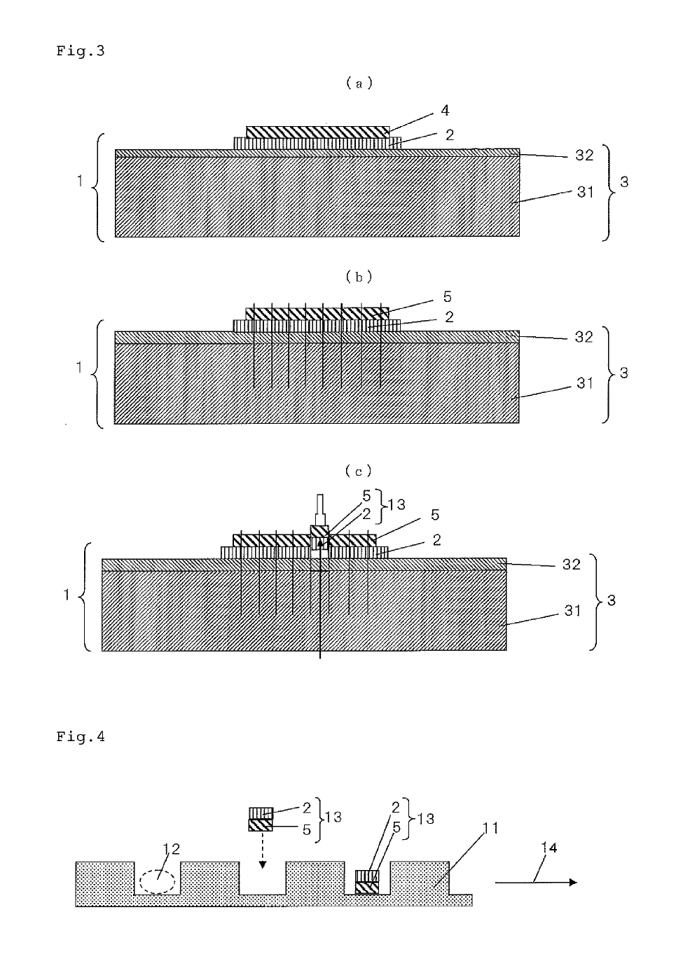

FIG. 3A to 3C are schematic sectional views showing one example of a method of manufacturing a semiconductor element.

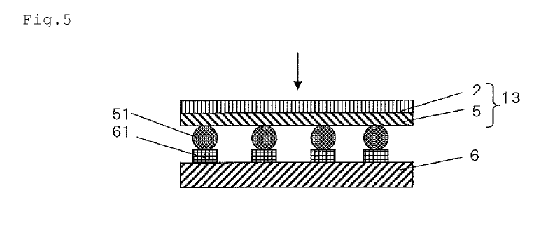

FIG. 4 is a schematic sectional view showing how a semiconductor element is inserted in a pocket of a carrier that can be wound up in a reel state.

FIG. 5 is a schematic sectional view showing a flip-chip semiconductor device.

### (1) Step 1

In the step 1, a semiconductor element 13 is inserted in a pocket 12 of a carrier 11 that can be wound up in a reel state.

### (1-1) Semiconductor Element 13

The semiconductor element 13 that can be used in the present invention is not especially limited, and examples thereof include a semiconductor chip 5 and the like. Among those, a semiconductor element preferably has a film 2 for the backside of a flip-chip semiconductor (also referred to as a film 2 for the backside of a semiconductor) that is formed on the backside of a semiconductor chip 5 that is flip-chip-connected to an adherend 6.

The semiconductor element 13 is preferably obtained with, for example, a method including a step A of laminating a dicing-tape integrated film 1 for the backside of a semiconductor, in which the film 2 for the backside of a flip-chip semiconductor that is formed on the backside of a semiconductor chip 5 that is flip-chip-connected to an adherend 6 is laminated onto a dicing tape 3, to a semiconductor wafer 4; a step B of dicing the semiconductor wafer 4 that is laminated by the film 1 for the backside of a flip-chip semiconductor; and a step C of picking up the semiconductor chip 5 obtained by dicing together with the film 2 for the backside of a flip-chip semiconductor to obtain the semiconductor element 13 having the film 2 for the backside of a flip-chip semiconductor.

### (1-1-A) Step A

In the step A, the dicing-tape integrated film 1 for the backside of a semiconductor is laminated to the semiconductor wafer 4.

### (Dicing-Tape Integrated Film 1 for the Backside of a Semiconductor)

As shown in FIG. 1, a dicing-tape integrated film 1 for the backside of a semiconductor has a dicing tape 3 in which a pressure-sensitive adhesive layer 32 is provided on a base 31 and a film 2 for the backside of a semiconductor that is provided on the pressure-sensitive adhesive layer 32. As shown in FIG. 1, the dicing-tape integrated film 1 for the backside of a semiconductor that can be used in the present invention may have a configuration in which the film 2 for the backside of a semiconductor is formed only on a portion 33 that corresponds to a pasting portion of a semiconductor wafer 4 on the pressure-sensitive adhesive layer 32 of the dicing tape 3. However, the film may have a configuration in which the film 2 for the backside of a semiconductor is formed on the entire surface of the pressure-sensitive adhesive layer 32, or it may have a configuration in which the film 2 for the backside of a semiconductor is formed on a portion that is larger than the portion 33 that corresponds to the pasting portion of the semiconductor wafer 4 and smaller than the entire surface of the pressure-sensitive adhesive layer 32. The surface (the surface that is pasted to the backside of the wafer) of the film 2 for the backside of a semiconductor may be protected with a separator, or the like until it is pasted to the backside of the wafer.

The film 2 for the backside of a semiconductor and the dicing tape 3 will be explained in detail below.

### (Film 2 for the Backside of a Semiconductor Wafer)

The film 2 for the backside of a semiconductor has a film-like form.

The film 2 for the backside of a semiconductor can be formed of, for example, a resin composition containing a thermoplastic resin and/or a thermosetting resin, and specifically it can be formed of a resin composition containing a thermoplastic resin and a thermosetting resin, a thermoplastic resin composition in which a thermosetting resin is not used, and a thermosetting resin composition in which a thermoplastic resin is not used. Among those, it is preferably formed of a resin composition containing a thermoplastic resin.

Examples of the thermoplastic resin include a natural rubber, a butyl rubber, an isoprene rubber, a chloroprene rubber, an ethylene-vinyl acetate copolymer, an ethylene-acrylate copolymer, an ethylene-acrylic ester copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as polyethylene terephthalate (PET) and polybutylene terephthalate (PBT), a polyamideimide resin, and a fluororesin. The thermoplastic resins can be used alone or two types or more can be used together. Of these thermoplastic resins, an acrylic resin is especially preferable from the viewpoints that the resin contains ionic impurities in only a small amount and has a high heat resistance so as to make it possible to ensure the reliability of the semiconductor element.

The acrylic resin is not especially limited, and examples thereof include a polymer having one type or two types or more of acrylates or methacrylates having a linear or branched alkyl group having 30 or less carbon atoms (preferably 1 to 18 carbon atoms, further preferably 1 to 10 carbon atoms, and especially preferably 1 to 5 carbon atoms) as a component. That is, the acrylic resin of the present invention has a broad meaning and also includes a methacrylic resin. Examples of the alkyl group include a methyl group, an ethyl group, a propyl group, an isopropyl group, an n-butyl group, a t-butyl group, an isobutyl group, a pentyl group, an isopentyl group, a hexyl group, a heptyl group, a 2-ethylhexyl group, an octyl group, an isooctyl group, a nonyl group, an isononyl group, a decyl group, an isodecyl group, an undecyl group, a dodecyl group (a lauryl group), a tridecyl group, a tetradecyl group, a stearyl group, and an octadecyl group.

Other monomers that can form the above-described acrylic resin are not especially limited as long as they are monomers other than acrylates or methacrylates having a linear or branched alkyl group having 30 or less carbon atoms. Examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl) methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl(meth)acrylate, and (meth)acryloyloxynaphthalenesulfonic acid; and monomers which contain a phosphoric acid group, such as 2-hydroxyethylacryloyl phosphate. (Meth)acrylate refers to an acrylate and/or a methacrylate, and every “(meth)” in the present invention has the same meaning.

The larger the content of the thermoplastic resin to the entire resin composition, the more preferable it is. The content of the thermoplastic resin to the entire resin composition is preferably 50% by weight or more, more preferably 60% by weight or more, and further preferably 70% by weight or more. When it is 50% by weight or more, the marking can be performed well on the film 2 for the backside of a semiconductor in an uncured state in the step 2 because the change of physical properties before and after thermal curing is small. In addition, the process margin can be extended.

On the other hand, the upper limit of the content of the thermoplastic resin to the entire resin composition is not especially limited. However, it is 95% by weight or less and preferably 90% by weight or less. When it is 90% by weight or less, a sufficient adhesive strength to a wafer can be exhibited.

Examples of the thermosetting resin include an epoxy resin, a phenol resin, an amino resin, an unsaturated polyester resin, a polyurethane resin, a silicone resin, and a thermosetting polyimide resin. The thermosetting resins can be used alone or two types or more can be used together. An epoxy resin having a small amount of ionic impurities that erode the semiconductor element 13 is especially suitable as the thermosetting resin. Further, a phenol resin can be suitably used as a curing agent for the epoxy resin.

The epoxy resin is not especially limited, and examples thereof include bifunctional epoxy resins and polyfunctional epoxy resins such as a bisphenol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a bisphenyl type epoxy resin, a naphthalene type epoxy resin, a fluorene type epoxy resin, a phenol novolak type epoxy resin, an ortho-cresol novolak type epoxy resin, a trishydroxyphenylmethane type epoxy resin, and a tetraphenylolethane type epoxy resin, a hydantoin type epoxy resin, a trisglycidylisocyanurate type epoxy resin, and a glycidylamine type epoxy resin.

Among the above-described epoxy resins, a novolak type epoxy resin, a biphenyl type epoxy resin, a trishydroxyphenylmethane type epoxy resin, and a tetraphenylolethane type epoxy resin are especially preferable. These epoxy resins are highly reactive with a phenol resin as a curing agent and are excellent in heat resistance.

The phenol resin acts as a curing agent for the epoxy resin, and examples thereof include novolak type phenol resins such as a phenol novolak resin, a phenol aralkyl resin, a cresol novolak resin, a tert-butylphenol novolak resin, and a nonylphenol novolak resin, a resol type phenol resin, and polyoxystyrenes such as polyparaoxystyrene. The phenol resins can be used alone or two types or more can be used together. Among these, a phenol novolak resin and a phenol aralkyl resin are especially preferable from the viewpoint of being able to improve the connection reliability of the semiconductor device.

The phenol resin is suitably compounded in the epoxy resin so that a hydroxyl group in the phenol resin to 1 equivalent of an epoxy group in the epoxy resin component becomes 0.5 equivalents to 2.0 equivalents, and more preferably 0.8 equivalents to 1.2 equivalents.

In the present invention, a thermal curing-accelerating catalyst of an epoxy resin and a phenol resin can be also used. The thermal curing-accelerating catalyst is not especially limited, and it can be appropriately selected from known thermal curing-accelerating catalysts. One thermal curing-accelerating catalyst alone can be used or two types or more of thermal curing-accelerating catalysts can be combined. Examples of the thermal curing-accelerating catalyst include an amine-based curing-accelerating catalyst, a phosphorous-based curing-accelerating catalyst, an imidazole-based curing-accelerating catalyst, a boron-based curing-accelerating catalyst, and a phosphorous-boron-based curing-accelerating catalyst.

The smaller the content of the thermosetting resin to the entire resin composition, the more preferable it is from the viewpoints that the marking can be performed well on the film 2 for the backside of a semiconductor in an uncured state in the step 2 because the change of physical properties before and after thermal curing is small and that the process margin can be extended. The upper limit of the content of the thermosetting resin to the entire resin composition is preferably 50% by weight or less, more preferably 40% by weight or less, and further preferably 30% by weight or less. The lower limit of the content of the thermosetting resin to the entire resin composition is not especially limited. However, it is 5% by weight or more and preferably 10% by weight or more. When it is 10% by weight or more, good adhesion to the semiconductor wafer 4 is obtained.

It is important that the film 2 for the backside of a semiconductor has tackiness (adhesion) to the backside (the surface where a circuit is not formed) of the semiconductor wafer 4.

The adhering strength (23° C., peeling angle 180°, peeling rate 300 mm/min) of the film 2 for the backside of a semiconductor to the semiconductor wafer 4 is preferably 1 N/10 mm wide or more, more preferably 2 N/10 mm wide or more, and further preferably 4 N/10 mm wide or more. The upper limit of the adhering strength is not especially limited. However, it is preferably 10 N/10 mm wide or less and more preferably 8 N/10 mm wide or less. By making the adhering strength 1 N/10 mm wide or more, the film 2 for the backside of a semiconductor wafer is pasted to the semiconductor wafer 4 and the semiconductor element 13 with excellent adhesion, and generation of floating and the like can be prevented. In addition, generation of chip flying can be prevented when dicing the semiconductor wafer 4. The adhering strength of the film 2 for the backside of a semiconductor wafer to the semiconductor wafer 4 is measured, for example, as follows.

### <Adhering Strength>

A pressure-sensitive adhesive tape (trade name: “BT315” manufactured by NITTO DENKO CORPORATION) is pasted to one surface of the film 2 for the backside of a semiconductor to reinforce the backside. After that, the semiconductor wafer 4 having a thickness of 0.6 mm is pasted to the surface of the film 2 for the backside of a semiconductor of 10 mm wide and 150 mm long, in which the backside is reinforced, with a thermal laminating method by reciprocating 2 kg of a roller once at 50° C. The laminated semiconductor wafer is allowed to stand still on a heated plate (50° C.) for 2 minutes, and then allowed to stand still at normal temperature (about 23° C.) for 20 minutes. Then, the film 2 for the backside of a semiconductor in which the backside is reinforced is peeled off at a temperature of 23° C. under conditions of a peeling angle of 180° C. and a tensile speed of 300 mm/min using a peeling tester (trade name: “Autograph AGS-J” manufactured by Shimadzu Corporation). The adhering strength is a value (N/10 mm wide) that is measured by peeling off the film 2 for the backside of a semiconductor at the interface with the semiconductor wafer 4.

In addition, a polyfunctional compound that reacts with a functional group at the end of a molecular chain of a polymer is preferably added as a crosslinking agent. With this addition, adhering characteristics at high temperature can be improved and heat resistance can be improved. The crosslinking agent is not especially limited, and a known crosslinking agent can be used. Specific examples thereof include an isocyanate crosslinking agent, an epoxy crosslinking agent, a melamine crosslinking agent, a peroxide crosslinking agent, a urea crosslinking agent, a metal alkoxide crosslinking agent, a metal chelate crosslinking agent, a metal salt crosslinking agent, a carbodiimide crosslinking agent, an oxazoline crosslinking agent, an aziridine crosslinking agent, and an amine crosslinking agent. An isocyanate crosslinking agent and an epoxy crosslinking agent are preferable. The crosslinking agents can be used alone or two type or more can be used together.

Examples of the isocyanate crosslinking agent include lower aliphatic polyisocyanates such as 1,2-ethylene diisocyanate, 1,4-butylene diisocyanate, and 1,6-hexamethylene diisocyanate; alicyclic polyisocyanates such as cyclopentylene diisocyanate, cyclohexylene diisocyanate, isophorone diisocyanate, hydrogenated tolylene diisocyanate, and hydrogenated xylene diisocyanate; and aromatic polyisocyanates such as 2,4-tolylene diisocyanate, 2,6-tolylene diisocyanate, 4,4′-diphenylmethane diisocyanate, and xylylene diisiocyanate. A trimethylolpropane/tolylene diisocyanate trimer adduct (tradename: Coronate L manufactured by Nippon Polyurethane Industry Co., Ltd.) and a trimethylolpropane/hexamethylene diisocyanate trimer adduct (tradename: Coronate HL manufactured by Nippon Polyurethane Industry Co., Ltd.) can also be used.

Examples of the epoxy crosslinking agent include N,N,N′,N′-tetraglycidyl-m-xylenediamine, diglycidylaniline, 1,3-bis(N,N-glycidylaminomethyl)cyclohexane, 1,6-hexanediol diglycidylether, neopentylglycol diglycidylether, ethyleneglycol diglycidylether, propyleneglycol diglycidylether, polyethyleneglycol diglycidylether, polypropyleneglycol diglycidylether, sorbitol polyglycidylether, glycerol polyglycidylether, pentaerythritol polyglycidylether, polyglyserol polyglycidylether, sorbitan polyglycidylether, trimethylolpropane polyglycidylether, diglycidyl adipate, diglycidyl o-phthalate, triglycidyl-tris(2-hydroxyethyl)isocyanurate, resorcin diglycidylether, bisphenol-s-diglycidyl ether, and an epoxy resin having two or more epoxy groups in the molecule.

The used amount of the crosslinking agent is not especially limited, and can be appropriately selected according to the level of crosslinking. Specifically, the used amount of the crosslinking agent is preferably, for example, 7 parts by weight or less and more preferably 0.05 parts by weight to 7 parts by weight to 100 parts by weight of a polymer component (especially, a polymer having a functional group at the end of the molecular chain). When the used amount of the crosslinking agent is more than 7 parts by weight to 100 parts by weight of the polymer component, the adhering strength tends to decrease. From the viewpoint of improving cohesive strength, the used amount of the crosslinking agent is preferably 0.05 parts by weight or more to 100 parts by weight of the polymer component.

In the present invention, it is possible to perform a crosslinking treatment by irradiation with an electron beam, an ultraviolet ray, or the like in place of using the crosslinking agent or together with a crosslinking agent.

The film 2 for the backside of a semiconductor is preferably colored. With this configuration, the film 2 for the backside of a semiconductor can exhibit an excellent marking property and an excellent appearance, and a semiconductor device can be obtained having an appearance with added value. Because the colored film 2 for the backside of a semiconductor has an excellent marking property, various information such as character information and pattern information can be given to a semiconductor element 13 or the surface where a circuit is not formed of the semiconductor device in which the semiconductor element 13 is marked through the film 2 for the backside of a semiconductor using various marking methods such as a printing method and a laser marking method. Especially, the information such as character information and pattern information that is given by marking can be recognized visually with excellent visibility by controlling the color. The film 2 for the backside of a semiconductor is preferably colored because the dicing tape 3 and the film 2 for the backside of a semiconductor can be easily distinguished, and workability or the like can be improved. It is possible to color-code the semiconductor device by product, for example. When the film 2 for the backside of a semiconductor is colored (when it is not colorless or transparent), the color is not especially limited. However, the color is preferably a dark color such as black, blue, or red, and black is especially preferable.

In this embodiment, the dark color means a dark color having L* that is defined in the L*a*b* color system of basically 60 or less (0 to 60). The L* is preferably 50 or less (0 to 50) and more preferably 40 or less (0 to 40).

The black color means a blackish color having L* that is defined in the L*a*b* color system of basically 35 or less (0 to 35). The L* is preferably 30 or less (0 to 30) and more preferably 25 or less (0 to 25). In the black color, each of a* and b* that is defined in the L*a*b* color system can be appropriately selected according to the value of L*. For example, both of a* and b* are preferably −10 to 10, more preferably −5 to 5, and especially preferably −3 to 3 (above all, 0 or almost 0).

In this embodiment, L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de I′Eclairage (CIE) in 1976, and means a color space that is called a CIE1976 (L*a*b*) color system. The L*a*b* color system is provided in JIS Z 8729 in the Japanese Industrial Standards.

When coloring the film 2 for the backside of a semiconductor, a coloring material (coloring agent) can be used according to the objective color. Various dark color materials such as black color materials, blue color materials, and red color materials can be suitably used, and especially the black color materials are suitable. The color materials may be any of pigments, dyes, and the like. The color materials can be used alone or two types or more can be used together. Any dyes such as acid dyes, reactive dyes, direct dyes, dispersive dyes, and cationic dyes can be used. The pigments are also not especially limited in the form, and may be appropriately selected from known pigments.

When dyes are used as the color materials, the film 2 for the backside of a semiconductor having uniform or almost uniform coloring concentration can be easily manufactured because the dyes disperse uniformly or almost uniformly due to dissolution in the film 2 for the backside of a semiconductor. Because of that, when the dyes are used as the color materials, the coloring concentration of the film 2 for the backside of a semiconductor can be made uniform or almost uniform, and the marking property and the appearance can be improved.

The black color material is not especially limited, and can be appropriately selected from inorganic black pigments and black dyes, for example. The black color material may be a color material mixture in which a cyan color material (blue-green color material), a magenta color material (red-purple color material), and a yellow color material are mixed together. The black color materials can be used alone or two types or more can be used together. The black color materials can be used also with other color materials other than black.

Specific examples of the black color materials include carbon black such as furnace black, channel black, acetylene black, thermal black, and lamp black, graphite (black lead), copper oxide, manganese dioxide, azo pigments such as azomethine azo black, aniline black, perylene black, titanium black, cyanine black, activated carbon, ferrite such as nonmagnetic ferrite and magnetic ferrite, magnetite, chromium oxide, iron oxide, molybdenum disulfide, chromium complex, complex oxide black, and anthraquinone organic black.

In the present invention, black dyes such as C. I. solvent black 3, 7, 22, 27, 29, 34, 43, and 70, C. I. direct black 17, 19, 22, 32, 38, 51, and 71, C. I. acid black 1, 2, 24, 26, 31, 48, 52, 107, 109, 110, 119, and 154, and C. I. disperse black 1, 3, 10, and 24; and black pigments such as C. I. pigment black 1 and 7 can be used as the black color material.

Examples of such black color materials that are available on the market include Oil Black BY, Oil Black BS, Oil Black HBB, Oil Black 803, Oil Black 860, Oil Black 5970, Oil Black 5906, and Oil Black 5905 manufactured by Orient Chemical Industries Co., Ltd.

Examples of color materials other than the black color materials include a cyan color material, a magenta color material, and a yellow color material. Examples of the cyan color material include cyan dyes such as C. I. solvent blue 25, 36, 60, 70, 93, and 95; and C. I. acid blue 6 and 45; and cyan pigments such as C. I. pigment blue 1, 2, 3, 15, 15:1, 15:2, 15:3, 15:4, 15:5, 15:6, 16, 17, 17:1, 18, 22, 25, 56, 60, 63, 65, and 66; C. I. vat blue 4 and 60; and C. I. pigment green 7.

Examples of the magenta color material include magenta dyes such as C. I. solvent red 1, 3, 8, 23, 24, 25, 27, 30, 49, 52, 58, 63, 81, 82, 83, 84, 100, 109, 111, 121, and 122; C. I. disperse red 9; C. I. solvent violet 8, 13, 14, 21, and 27; C. I. disperse violet 1; C. I. basic red 1, 2, 9, 12, 13, 14, 15, 17, 18, 22, 23, 24, 27, 29, 32, 34, 35, 36, 37, 38, 39, and 40; and C. I. basic violet 1, 3, 7, 10, 14, 15, 21, 25, 26, 27, and 28.

Examples of the magenta color material include magenta pigments such as C. I. pigment red 1, 2, 3, 4, 5, 6, 7, 8, 9, 10, 11, 12, 13, 14, 15, 16, 17, 18, 19, 21, 22, 23, 30, 31, 32, 37, 38, 39, 40, 41, 42, 48:1, 48:2, 48:3, 48:4, 49, 49:1, 50, 51, 52, 52:2, 53:1, 54, 55, 56, 57:1, 58, 60, 60:1, 63, 63:1, 63:2, 64, 64:1, 67, 68, 81, 83, 87, 88, 89, 90, 92, 101, 104, 105, 106, 108, 112, 114, 122, 123, 139, 144, 146, 147, 149, 150, 151, 163, 166, 168, 170, 171, 172, 175, 176, 177, 178, 179, 184, 185, 187, 190, 193, 202, 206, 207, 209, 219, 222, 224, 238, and 245; C. I. pigment violet 3, 9, 19, 23, 31, 32, 33, 36, 38, 43, and 50; and C. I. vat red 1, 2, 10, 13, 15, 23, 29, and 35.

Examples of the yellow color material include yellow dyes such as C. I. solvent yellow 19, 44, 77, 79, 81, 82, 93, 98, 103, 104, 112, and 162; and yellow pigments such as C. I. pigment orange 31 and 43, C. I. pigment yellow 1, 2, 3, 4, 5, 6, 7, 10, 11, 12, 13, 14, 15, 16, 17, 23, 24, 34, 35, 37, 42, 53, 55, 65, 73, 74, 75, 81, 83, 93, 94, 95, 97, 98, 100, 101, 104, 108, 109, 110, 113, 114, 116, 117, 120, 128, 129, 133, 138, 139, 147, 150, 151, 153, 154, 155, 156, 167, 172, 173, 180, 185, and 195, and C. I. vat yellow 1, 3, and 20.

Various color materials such as cyan color materials, magenta color materials, and yellow color materials can be used alone or two types or more can be used together. When two types or more of various color materials such as cyan color materials, magenta color materials, and yellow color materials are used, the mixing ratio or the compounding ratio of these color materials is not especially limited, and can be appropriately selected according to the types of each color material and the intended color.

The content of the coloring agent is preferably 0.01 parts by weight to 10 parts by weight, more preferably 0.5 parts by weight to 8 parts by weight, and further preferably 1 part by weight to 5 parts by weight to 100 parts by weight of the resin composition (entire component other than solvent including resin, filler, and coloring agent). By making the content 0.01 parts by weight or more, the light transmittance can be decreased and the contrast can be increased between a marking portion where a laser marking is applied and a portion other than the marking portion. The film 2 for the backside of a semiconductor may be of a single layer or may be a laminated film in which a plurality of layers are laminated. In the case of a laminated film, the content of the coloring agent may be in a range of 0.01 parts by weight to 10 parts by weight as a whole laminated film.

When coloring the film 2 for the backside of a semiconductor, the colored state of the layers is not especially limited. For example, the film 2 for the backside of a semiconductor may be of a single layered film in which a coloring agent is added or may be a laminated film in which at least a resin layer formed of a resin composition and a coloring agent layer are laminated. When the film 2 for the backside of a semiconductor is in the form of a laminated film of the resin layer and the coloring agent layer, the film 2 for the backside of a semiconductor preferably has a laminated state of a resin layer/a coloring agent layer/a resin layer. In this case, the two resin layers on both sides of the coloring agent layer may be resin layers having the same composition or may be resin layers having different compositions.

When the film 2 for the backside of a semiconductor that can be used in the present invention is formed of a resin composition containing a thermosetting resin, the tensile storage modulus at 23° C. of the uncured film 2 for the backside of a semiconductor is preferably 10 MPa to 10 GPa, more preferably 100 MPa to 5 GPa, further preferably 100 MPa to 3 GPa, furthermore preferably 100 MPa to 1 GPa, and especially preferably 100 MPa to 0.7 GPa. By making the modulus 10 GPa or less, adhesion with the semiconductor wafer 4 can be sufficiently secured.

The film 2 for the backside of a semiconductor may be of a single layer or may be a laminated film in which a plurality of layers are laminated. In the case of a laminated film, the storage modulus of the uncured film at 23° C. may be within the above-described range as a whole laminated film. The tensile storage modulus (23° C.) in the uncured portion of the film 2 for the backside of a semiconductor can be controlled by the type and the content of the resin component (a thermoplastic resin and a thermosetting resin), the type and the content of the filler such as a silica filler, and the like.

The uncured film 2 for the backside of a semiconductor was produced without laminating the films on the dicing tape 3, and the tensile storage modulus was measured using a dynamic viscoelasticity measurement apparatus (Solid Analyzer RS A2) manufactured by Rheometric Scientific FE, Ltd. in tensile mode, sample width 10 mm, sample length 22.5 mm, sample thickness 0.2 mm, frequency 1 Hz, temperature rise rate 10° C./min, under a nitrogen atmosphere, and at a prescribed temperature (23° C.).

When the film 2 for the backside of a semiconductor that can be used in the present invention is formed of a resin composition containing a thermosetting resin, the modulus after the film 2 for the backside of a semiconductor is cured is preferably 10 MPa to 10 GPa, more preferably 100 MPa to 5 GPa, further preferably 100 MPa to 3 GPa, and especially preferably 100 MPa to 1 GPa. The modulus is measured in the same manner as in the measurement described above except that the film 2 for the backside of a semiconductor is cured (175° C., 1 hour).

Other additives can be appropriately compounded in the film 2 for the backside of a semiconductor as necessary. Examples of the other additives include a filler, a flame retardant, a silane coupling agent, an ion trapping agent, an extender, an anti-aging agent, an antioxidant, and a surfactant.

The filler may be any of an inorganic filler and an organic filler. However, an inorganic filler is preferable. By adding a filler such as an inorganic filler, electric conductivity can be given to the film 2 for the backside of a semiconductor, heat conductivity can be improved, and the elastic modulus can be adjusted. The film 2 for the backside of a semiconductor may be electrically conductive or non-conductive. Examples of the inorganic filler include ceramics such as silica, clay, gypsum, calcium carbonate, barium sulfate, alumina oxide, beryllium oxide, silicon carbide, and silicon nitride, metals such as aluminum, copper, silver, gold, nickel, chromium, lead, tin, zinc, palladium, and solder, alloys, and various inorganic powders consisting of carbon. The fillers may be used alone or two types or more can be used together. Among these, silica, especially molten silica is preferable. The average particle size of the inorganic filler is preferably in a range of 0.1 μm to 80 μm. The average particle size of the inorganic filler can be measured with a laser diffraction type particle size distribution device, for example.

The compounding amount of the filler is preferably 80 parts by weight or less, and especially preferably 0 parts to 75 parts by weight to 100 parts by weight of the resin component.

Examples of the flame retardant include antimony trioxide, antimony pentoxide, and a brominated epoxy resin. These can be used alone or two types or more can be used together. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These compounds can be used alone or two types or more can be used together. Examples of the ion trap agent include hydrotalcites and bismuth hydroxide. These can be used alone or two types or more can be used together.

The film 2 for the backside of a semiconductor can be formed by a common method of mixing a thermoplastic resin such as an acrylic resin, optionally a thermosetting resin such as an epoxy resin, and optionally a solvent, other additives, and the like to prepare a resin composition and forming the composition into a film layer. Specifically, a film layer (an adhesive layer) as the film 2 for the backside of a semiconductor can be formed by a method of applying the resin composition onto the pressure-sensitive adhesive layer 32 of the dicing tape 3, a method of applying the resin composition onto an appropriate separator such as release paper to form a resin layer (or an adhesive layer) and transcribing (transferring) the resin layer onto the pressure-sensitive adhesive layer 32, or the like. The resin composition may be a solution or a dispersion liquid.

Because cutting water is used in the step B that is described later, the film 2 for the backside of a semiconductor may absorb moisture and the water content may exceed the normal value. When flip-chip bonding is performed with such a high water content, water vapor is accumulated in the boundary between the film 2 for the backside of a semiconductor and a semiconductor wafer 4 or a processed body thereof (a semiconductor), and floating may occur. Therefore, to avoid such a problem, the film 2 for the backside of a semiconductor is made to have a configuration in which a core material having high moisture permeability is provided on both surfaces thereof to diffuse water vapor. From such a viewpoint, a multilayered structure in which films for the backside of a semiconductor are formed on one surface or both surfaces of the core material may be used as the film 2 for the backside of a semiconductor. Examples of the core material include a film such as a polyimide film, a polyester film, a polyethylene terephthalate film, a polyethylene naphthalate film, or a polycarbonate film, a resin substrate reinforced by a glass fiber or a plastic nonwoven fiber, a silicon substrate, or a glass substrate.

The thickness (total thickness in the case of a laminated film) of the film 2 for the backside of a semiconductor is not especially limited. However, the thickness can be appropriately selected from a range of about 2 μm to 200 μm. The thickness is preferably about 4 μm to 160 μm, more preferably about 6 μm to 100 μm, and especially preferably about 10 μm to 80 μm.

### (Dicing Tape 3)

The dicing tape 3 has a configuration in which the pressure-sensitive adhesive layer 32 is formed on the base 31.

The base (support base) 31 can be used as a support base body of the pressure-sensitive adhesive layer 32, and the like. The base 31 preferably has radiation transparency. Examples of the base 31 include appropriate thin materials including paper bases such as paper; fiber bases such as cloth, unwoven cloth, felt, and net; metal bases such as a metal foil and a metal plate; plastic bases such as a plastic film and sheet; rubber bases such as a rubber sheet; foams such as a foamed sheet, and laminated bodies of these (especially laminated bodies of a plastic base and other bases and laminated bodies of plastic films or sheets). Of these bases, a plastic base such as a plastic film or sheet can be preferably used as the base 31.

Examples of the material of such a plastic base include olefin resins such as polyethylene (PE), polypropylene (PP), and an ethylene-propylene copolymer; copolymers having ethylene as a monomer component such as an ethylene vinyl acetate copolymer (EVA), an ionomer resin, an ethylene-(meth)acrylate copolymer, and an ethylene-(meth)acrylate (random, alternating) copolymer; polyesters such as polyethylene terephthalate (PET), polyethylene naphthalate (PEN), and polybutylene terephthalate (PBT); an acrylic resin; polyvinyl chloride (PVC); polyurethane; polycarbonate; polyphenylene sulfide (PPS); amide resins such as polyamide (nylon) and fully aromatic polyamide (aramid); polyether ether ketone (PEEK); polyimide; polyetherimide; polyvinylidene chloride; ABS (acrylonitrile-butadiene-styrene copolymer); a cellulose resin; a silicone resin; and a fluororesin.

Further, the material of the base 31 includes a cross-linked body of the above resin. The above plastic film may be also used unstreched, or may be also used on which a monoaxial or a biaxial stretching treatment is performed depending on necessity. According to resin sheets in which heat shrinkable properties are given by the stretching treatment, etc., the adhesive area of the pressure-sensitive adhesive layer 32 and the film 2 for the backside of a semiconductor are reduced by thermally shrinking the base 31 after dicing, and the recovery of the semiconductor chips (a semiconductor element) can be facilitated.

A known surface treatment such as a chemical or physical treatment such as a chromate treatment, ozone exposure, flame exposure, high voltage electric exposure, and an ionized ultraviolet treatment, and a coating treatment by an undercoating agent (for example, a tacky substance described later) can be performed on the surface of the base 31 in order to improve adhesiveness, holding properties, etc. with the adjacent layer.

The same type or different types can be appropriately selected and used as the base 31, and several types can be blended and used as necessary. A vapor deposited layer of a conductive substance having a thickness of about 30 Å to 500 Å consisting of metals, alloys, and oxides of these can be provided on the base 31 to give an antistatic function to the base 31. The base 31 maybe a single layer or a multilayer consisting of two types or more layers.

The thickness (total thickness in the case of a laminated film) of the base 31 is not especially limited, and it can be appropriately selected depending on the strength, flexibility, purpose of use, etc., and it is generally 1,000 μm or less, preferably 1 μm to 1,000 μm, more preferably 10 μm to 500 μm, further preferably 20 μm to 300 μm, and especially preferably about 30 μm to 200 μm.

The base 31 may contain various additives such as a coloring agent, a filler, a plasticizer, an anti-aging agent, an antioxidant, a surfactant, and a flame retardant as long as the effects of the present invention are not deteriorated.

The pressure-sensitive adhesive layer 32 is formed with a pressure-sensitive adhesive, and has adherability. The pressure-sensitive adhesive is not especially limited, and can be appropriately selected among known pressure-sensitive adhesives. Specifically, known pressure-sensitive adhesives (refer to Japanese Patent Application Laid-Open Nos. 56-61468, 61-174857, 63-17981, and 56-13040, for example) such as a pressure-sensitive adhesive having the above-described characteristics can be appropriately selected from an acrylic pressure-sensitive adhesive, a rubber pressure-sensitive adhesive, a vinylalkylether pressure-sensitive adhesive, a silicone pressure-sensitive adhesive, a polyester pressure-sensitive adhesive, a polyamide pressure-sensitive adhesive, a urethane pressure-sensitive adhesive, a fluorine pressure-sensitive adhesive, a styrene-diene block copolymer pressure-sensitive adhesive, and a creep property improved pressure-sensitive adhesive in which a hot-melt resin having a melting point of about 200° C. or less is compounded in these pressure-sensitive adhesives. A radiation curing type pressure-sensitive adhesive (or an energy ray curing type pressure-sensitive adhesive) and a thermally expandable pressure-sensitive adhesive can also be used as the pressure-sensitive adhesive. The pressure-sensitive adhesives can be used alone or two types or more can be used together.

An acrylic pressure-sensitive adhesive and a rubber pressure-sensitive adhesive can be suitably used as the pressure-sensitive adhesive, and especially an acrylic pressure-sensitive adhesive is suitable. An example of the acrylic pressure-sensitive adhesive is an acrylic pressure-sensitive adhesive having an acrylic polymer, in which one type or two types or more of alkyl(meth)acrylates are used as a monomer component, as a base polymer.

Examples of alkyl(meth)acrylates in the acrylic pressure-sensitive adhesive include methyl(meth)acrylate, ethyl(meth)acrylate, propyl(meth)acrylate, isopropyl(meth)acrylate, butyl(meth)acrylate, isobutyl(meth)acrylate, s-butyl(meth)acrylate, t-butyl(meth)acrylate, pentyl(meth)acrylate, hexyl(meth)acrylate, heptyl(meth)acrylate, octyl(meth)acrylate, 2-ethylhexyl(meth)acrylate, isooctyl(meth)acrylate, nonyl(meth)acrylate, isononyl(meth)acrylate, decyl(meth)acrylate, isodecyl(meth)acrylate, undecyl(met)acrylate, dodecyl(meth)acrylate, tridecyl(meth)acrylate, tetradecyl(meth)acrylate, pentadecyl(meth)acrylate, hexadecyl(meth)acrylate, heptadecyl(meth)acrylate, octadecyl(meth)acrylate, nonadecyl(meth)acrylate, and eicosyl(meth)acrylate. Alkyl(meth)acrylates having an alkyl group of 4 to 18 carbon atoms is suitable. The alkyl group of alkyl(meth)acrylates may be any of linear or branched chain.

The acrylic polymer may contain units that correspond to other monomer components that is copolymerizable with alkyl(meth)acrylates described above (copolymerizable monomer component) for reforming cohesive strength, heat resistance, and crosslinking property, as necessary. Examples of such copolymerizable monomer components include carboxyl group-containing monomers such as (meth)acrylic acid (acrylic acid, methacrylic acid), carboxyethyl acrylate, carboxypentyl acrylate, itaconic acid, maleic acid, fumaric acid, and crotonic acid; acid anhydride group-containing monomers such as maleic anhydride and itaconic anhydride; hydroxyl group-containing monomers such as hydroxyethyl(meth)acrylate, hydroxypropyl(meth)acrylate, hydroxybutyl(meth)acrylate, hydroxyhexyl(meth)acrylate, hydroxyoctyl(meth)acrylate, hydroxydecyl(meth)acrylate, hydroxylauryl(meth)acrylate, and (4-hydroxymethylcyclohexyl)methyl methacrylate; sulfonate group-containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid; phosphate group-containing monomers such as 2-hydroxyethylacryloylphosphate; (N-substituted) amide monomers such as (meth)acrylamide, N,N-dimethyl(meth)acrylamide, N-butyl(meth)acrylamide, N-methylol(meth)acrylamide, and N-methylolpropane(meth)acrylamide; aminoalkyl(meth)acrylate monomers such as aminoethyl(meth)acrylate, N,N-dimethlaminoethyl(meth)acrylate, and t-butylaminoethyl(meth)acrylate; alkoxyalkyl(meth)acrylate monomers such as methoxyethyl(meth)acrylate and ethoxyethyl(meth)acrylate; cyanoacrylate monomers such as acrylonitrile and methacrylonitrile; epoxy group-containing acrylic monomers such as glycidyl(meth)acrylate; styrene monomers such as styrene and α-methylstyrene; vinylester monomers such as vinyl acetate and vinyl propionate; olefin monomers such as isoprene, butadiene, and isobutylene; vinylether monomers such as vinylether; nitrogen-containing monomers such as N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, N-vinylcarboxylic acid amides, and N-vinylcaprolactam; maleimide monomers such as N-cyclohexylmaleimide, N-isopropylmaleimide, N-laurylmaleimide, and N-phenylmaleimide; itaconimide monomers such as N-methylitaconimide, N-ethylitaconimide, N-butylitaconimide, N-octylitaconimide, N-2-ethylhexylitaconimide, N-cyclohexylitaconimide, and N-laurylitaconimide; succinimide monomers such as N-(meth)acryloyloxymethylene succinimide, N-(meth)acryloyl-6-oxyhexamethylene succinimide, and N-(meth)acryloyl-8-oxyoctamethylene succinimide; glycol acrylester monomers such as polyethylene glycol(meth)acrylate, polypropylene glycol(meth)acrylate, metoxyethylene glycol(meth)acrylate, and metoxypolypropylene glycol(meth)acrylate; acrylate monomers having a heterocyclic ring, a halogen atom, a silicon atom, and the like such as tetrahydrofurfuryl(meth)acrylate, fluorine(meth)acrylate, and silicone(meth)acrylate; and polyfunctional monomers such as hexanediol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylolpropane tri(meth)acrylate, pentaerythritol tri(meth)acrylate, dipentaerythritol hexa(meth)acrylate, epoxyacrylate, polyesteracrylate, urethaneacrylate, divinylbenzene, butyl di(meth)acrylate, and hexyl di(meth)acrylate. One type or two types or more of these copolymerizable monomer components can be used.

When a radiation curing type pressure-sensitive adhesive (or an energy ray curing type pressure-sensitive adhesive) is used as the pressure-sensitive adhesive, examples of the radiation curing type pressure-sensitive adhesive (composition) include an internal radiation curing type pressure-sensitive adhesive having a polymer with a radical reactive carbon-carbon double bond in the polymer side chain, the main chain, or the ends of the main chain as a base polymer and a radiation curing type pressure-sensitive adhesive in which ultraviolet-ray curing-type monomer component and oligomer component are compounded in the pressure-sensitive adhesive. When a thermally expandable pressure-sensitive adhesive is used as the pressure-sensitive adhesive, examples thereof include a thermally expandable pressure-sensitive adhesive containing a pressure-sensitive adhesive and a foaming agent (especially, a thermally expandable microsphere).

The pressure-sensitive adhesive layer 32 of the present invention may contain various additives such as a tackifier, a coloring agent, a thickener, an extender, a filler, a plasticizer, an anti-aging agent, an antioxidant, a surfactant, and a crosslinking agent as long as the effects of the present invention are not deteriorated.

The crosslinking agent is not especially limited, and known crosslinking agents can be used. Specific examples of the crosslinking agent include an isocyanate crosslinking agent, an epoxy crosslinking agent, a melamine crosslinking agent, a peroxide crosslinking agent, a urea crosslinking agent, a metal alkoxide crosslinking agent, a metal chelate crosslinking agent, a metal salt crosslinking agent, a carbodiimide crosslinking agent, an oxazoline crosslinking agent, an aziridine crosslinking agent, and an amine crosslinking agent, and an isocyanate crosslinking agent and an epoxy crosslinking agent are preferable. The crosslinking agents can be used alone or two types or more can be used together. The used amount of the crosslinking agent is not especially limited.

Examples of the isocyanate crosslinking agent can include the same isocyanate crosslinking agents as those that are exemplified herein as the isocyanate crosslinking agents that can be added in the resin composition for the film 2 for the backside of a semiconductor.

In the present invention, a crosslinking treatment can be performed by irradiation with an electron beam, an ultraviolet ray, or the like instead of using the crosslinking agent or in addition to the use of the crosslinking agent.

The pressure-sensitive adhesive layer 32 can be formed by a common method of forming a sheet-like layer by mixing the pressure-sensitive adhesive with a solvent, other additives, and the like as necessary. Specifically, the pressure-sensitive adhesive layer 32 can be produced by a method of applying the pressure-sensitive adhesive or a mixture containing the pressure-sensitive adhesive, a solvent and other additives to the base 31, a method of forming the pressure-sensitive adhesive layer 32 by applying the above-described mixture to an appropriate separator (release paper, for example), and transferring (adhering) the resultant onto the base 31, for example.

The thickness of the pressure-sensitive adhesive layer 32 is not especially limited. However, it is preferably 5 μm to 300 μm, more preferably 5 μm to 200 μm, further preferably 5 μm to 100 μm, and especially preferably about 7 μm to 50 μm. When the thickness of the pressure-sensitive adhesive layer 32 is in the above-described range, adequate adhesive power can be exhibited. The pressure-sensitive adhesive layer 32 may be a single layer or a plurality of layers.

The adhering strength (23° C., peeling angle 180°, peeling speed 300 mm/min) of the pressure-sensitive adhesive layer 32 of the dicing tape 3 to the film 2 for the backside of a flip-chip semiconductor is preferably in a range of 0.02 N/20 mm to 10 N/20 mm, and more preferably 0.05 N/20 mm to 5 N/20 mm. By making the adhering strength 0.02 N/20 mm or more, chip flying of a semiconductor element can be prevented when dicing the semiconductor wafer. Meanwhile, by making the adhering strength 10 N/20 mm or less, difficulty in peeling the semiconductor element off and generation of adhesive residue can be prevented when picking the semiconductor element up.

The film 2 for the backside of a flip-chip type semiconductor and the dicing tape-integrated film 1 for the backside of a semiconductor may be formed in a form in which the films are wound into a roll or a form in which the films are laminated.

The thickness (total thickness of the thickness of the film 2 for the backside of a semiconductor and the thickness of the dicing tape 3 made of the base 31 and the pressure-sensitive adhesive layer 32) of the dicing tape-integrated film 1 for the backside of a semiconductor can be selected from a range of 8 μm to 1500 μm, preferably 20 μm to 850 μm, more preferably 31 μm to 500 μm, and especially preferably 47 μm to 330 μm.

By controlling the ratio between the thickness of the film 2 for the backside of a semiconductor and the thickness of the pressure-sensitive adhesive layer 32 of the dicing tape 3 and the ratio between the thickness of the film 2 for the backside of a semiconductor and the thickness of the dicing tape 3 (total thickness of the base 31 and the pressure-sensitive adhesive layer 32) in the dicing tape-integrated film 1 for the backside of a semiconductor, the dicing property in a dicing step, the pickup property in a pickup step, and the like can be improved, and the dicing tape-integrated film 1 for the backside of a semiconductor can be effectively used from the dicing step of a semiconductor wafer 4 to the flip-chip bonding step of a semiconductor element 13.

The method of manufacturing the dicing-tape integrated film 1 for the backside of a semiconductor will be explained. First, the base 31 can be formed by a conventionally known film forming method. Examples of the film forming method include a calender film forming method, a casting method in an organic solvent, an inflation extrusion method in a closed system, a T die extrusion method, a co-extrusion method, and a dry laminating method.

The pressure-sensitive adhesive layer 32 is formed by applying a pressure-sensitive adhesive composition to the base 31 and drying the composition (by crosslinking by heat as necessary). Examples of the application method include roll coating, screen coating, and gravure coating. The pressure-sensitive adhesive layer 32 may be formed on the base 31 by applying the pressure-sensitive adhesive composition directly to the base 31, or the pressure-sensitive adhesive layer 32 may be transferred to the base 31 after the pressure-sensitive adhesive layer 32 is formed by applying the pressure-sensitive adhesive composition to a release paper whose surface has been subjected to a release treatment. With this configuration, the dicing tape 3 is produced in which the pressure-sensitive adhesive layer 32 is formed on the base 31.

The material for forming the film 2 for the backside of a semiconductor is applied onto release paper to have a prescribed thickness after drying, and further dried under a prescribed condition to form a coating layer. The coating layer is transcribed onto the pressure-sensitive adhesive layer 32 to form the film 2 for the backside of a semiconductor on the pressure-sensitive adhesive layer 32. The material for forming the film 2 for the backside of a semiconductor can be directly applied onto the pressure-sensitive adhesive layer 32 and dried under a prescribed condition to form the film 2 for the backside of a semiconductor on the pressure-sensitive adhesive layer 32. With the above, the dicing tape-integrated film 1 for the backside of a semiconductor according to the present invention can be obtained.

### (Semiconductor Wafer 4)

The semiconductor wafer 4 is not especially limited as long as it is a known or common semiconductor wafer, and semiconductor wafers made of various materials can be appropriately selected and used. In the present invention, a silicon wafer can be suitably used as the semiconductor wafer 4.

As shown in FIG. 3(a), the separator that is appropriately provided on the film 2 for the backside of a semiconductor of the dicing tape-integrated film 1 for the backside of a semiconductor is appropriately peeled off, a semiconductor wafer 4 is pasted to the film 2 for the backside of a semiconductor, and the laminate is fixed by adhering and holding (a mounting step). The dicing tape-integrated film 1 for the backside of a semiconductor is pasted to the backside of the semiconductor wafer 4. The backside of the semiconductor wafer 4 means the surface opposite to the circuit forming surface (also referred to as a non-circuit surface or a non-electrode forming surface). The pasting method is not especially limited, and a pasting method by pressure-bonding is preferable. The pressure-bonding is performed by pressing by a pressing means such as a press roll.

### (1-1-B) Step B

As shown in FIG. 3(b), dicing of the semiconductor wafer 4 is performed. With this operation, the semiconductor wafer 4 is cut into individual pieces (cut into small pieces) having a prescribed size, and a semiconductor chip 5 is manufactured. The dicing is performed from the circuit surface side of the semiconductor wafer 4 by a normal method, for example. For example, a cutting method called full cut in which cutting is performed up to the dicing tape-integrated film 1 for the backside of a semiconductor can be adopted in this step. The dicing apparatus used in this step is not especially limited, and a conventionally known apparatus can be used. Because the semiconductor wafer 4 is adhered and fixed with excellent adhesion by the dicing tape-integrated film 1 for the backside of a semiconductor having the film 2 for the backside of a semiconductor, chip cracks and chip fly can be suppressed and damages to the semiconductor wafer 4 can also be suppressed. When the film 2 for the backside of a semiconductor is formed of a resin composition containing an epoxy resin, the occurrence of protrusion of the adhesive layer of the film 2 for the backside of a semiconductor at a surface cut by dicing can be suppressed or prevented. As a result, reattachment (blocking) of the cut surfaces can be suppressed or prevented, and pickup described later can be performed more favorably.

### (1-1-C) Step C

The semiconductor chip 5 is peeled from the dicing tape 3 together with the film 2 for the backside of a semiconductor by performing pickup of the semiconductor chip 5 as shown in FIG. 3(c) to collect the semiconductor chip 5 that is adhered and fixed to the dicing tape-integrated film 1 for the backside of a semiconductor. The pickup method is not especially limited, and various conventionally known methods can be adopted. An example of the method is a method of pushing up an individual semiconductor chip 5 from the side of the base 31 of the dicing tape-integrated film 1 for the backside of a semiconductor with a needle and picking up the pushed semiconductor chip 5 with a pickup apparatus. The backside of the semiconductor chip 5 that is picked up is protected by the film 2 for the backside of a semiconductor.

When expanding the dicing tape-integrated film 1 for the backside of a semiconductor, a conventionally known expanding apparatus can be used. The expanding apparatus has a donut-shaped outer ring that can push down the dicing tape-integrated film 1 for the backside of a semiconductor through a dicing ring and an inner ring that has a smaller diameter than the outer ring and that supports the dicing tape-integrated film for the backside of a semiconductor. With this expanding step, generation of damage caused by the contact between adjacent semiconductor chips 5 can be prevented in the pickup step.

### (1-2) Carrier 11

A conventionally known carrier can be used as a carrier 11 as long as it can be wound up in a reel state. A plurality of pockets (a concave portion where the semiconductor element 13 is inserted) 12 are normally formed in the carrier 11 with a prescribed pitch in a longitudinal direction. Examples of the carrier 11 include an embossed carrier tape and a press carrier tape (a press pocket carrier tape). Examples thereof also include a carrier tape in which a conventionally known bottom tape is pasted to the backside of a punched carrier tape (a carrier tape with a through hole), and the like.

The pocket 12 is not especially limited as long as it has a concave portion where the semiconductor element 13 can be inserted. Examples thereof include a concave portion that is formed by a compressing process such as an embossing process. Examples thereof also include a concave portion in which a conventionally known bottom tape is pasted to the backside of a carrier tape with a through hole; and the like. One semiconductor element 13 is normally inserted in each pocket 12.

The insertion can be performed using a taping apparatus while sending (winding up) the carrier 11 to a reel. The taping apparatus is not especially limited, and a conventionally known apparatus can be used.

The insertion method is not especially limited, and examples thereof include a method of stopping sending the carrier 11 and inserting the semiconductor element 13; a method of inserting the semiconductor element 13 while sending (not stopping) the carrier 11; and the like. The method of stopping sending the carrier 11 and inserting the semiconductor element 13 is preferable from the viewpoint that the semiconductor element 13 can be inserted accurately.

The stopping time is not especially limited. However, it is normally 0.01 seconds to 100 seconds and preferably 0.5 seconds to 10 seconds.

### (2) Step 2

In the step 2, marking is performed on the semiconductor element 13 that is inserted in the pocket 12 in the step 1.

The marking is not especially limited as long as it is performed after the semiconductor element 13 is inserted in the pocket 12. However, it is preferable to perform the marking while the sending of the carrier 11 is stopped (within the above-described stopping time). With this step, an independent step for marking is not necessary, and a semiconductor device can be manufactured effectively. In addition, the marking can be performed accurately because the semiconductor element 13 is in a stopping state. As a result, a semiconductor device is obtained with excellent visibility of various information such as character information and graphic information.

The alignment (aligning the position) is performed before marking. The alignment method is not especially limited, and can be performed with a conventionally known method. Normally in the step 2, the positional shift of each semiconductor element 13 is slight and it can be effectively aligned because the semiconductor element 13 is continuously sent to a region where the alignment mark can be detected by the carrier 11. As a result, a semiconductor device can be effectively manufactured.

The marking is performed on the semiconductor element 13. The marking is performed normally on the backside of the semiconductor element 13. The backside of the semiconductor element 13 means the surface opposite to the circuit forming surface (also referred to as a non-circuit surface or a non-electrode forming surface). The film 2 for the backside of a semiconductor is formed on the backside of the semiconductor element 13 that can be obtained in the steps A to C.

When the semiconductor element 13 has the film 2 for the backside of a semiconductor, it is preferable to mark the film 2 for the backside of a semiconductor. When the film 2 for the backside of a semiconductor that can be used in the present invention is formed of a resin composition containing a thermosetting resin, it is more preferable to mark the uncured film 2 for the backside of a semiconductor. The “uncured state” is same as the state that in defined herein.

The marking method is not especially limited, and various marking methods can be used such as a printing method and a laser marking method. Among these methods, a laser marking is preferable. With this method, the marking can be performed with an excellent contrast ratio, and various information such as character information and graphic information marked by marking can be visually recognized well.

A known laser marking apparatus can be used when performing laser marking. Various lasers such as a gas laser, a solid laser, and a liquid laser can be used. Specifically, the gas laser is not especially limited, and a known gas laser can be used. However, a carbon dioxide gas laser (CO₂ laser) and an excimer laser such as an ArF laser, a KrF laser, an XeCl laser, or an XeF laser are suitable. The solid laser is not especially limited, and a known solid laser can be used. However, a YAG laser such as an Nd:YAG laser and a YVO₄ laser are suitable.

The irradiation conditions of a laser when performing a laser marking are appropriately set by considering the contrast between the marking portion and the portion other than the marking portion, the process depth, etc. The conditions can be set within the following ranges when a laser marking apparatus (trade name: “MD-59900” manufactured by KEYENCE CORPORATION) is used.

### (Laser Irradiation Conditions)

### Wavelength: 532 nm

### Intensity: 1.0 W

Scan speed: 700 mm/sec
Q-switch frequency: 64 kHz

### (3) Step 3

The method of manufacturing a semiconductor device of the present invention preferably include a step 3.

In the step 3, a cover tape is pasted to the carrier 11 to seal the semiconductor element 13 that is marked in the step 2. The cover tape is not especially limited, and a conventionally known cover tape can be used. The pasting method is not also especially limited.

When the film 2 for the backside of a semiconductor that can be used in the present invention is formed of a resin composition containing a thermosetting resin, the film 2 for the backside of a semiconductor provided in the semiconductor element 13 of the step 3 is preferably in an uncured state. The “uncured state” refers to a state before being cured completely, and includes a semicured state in which the crosslinking reaction is advanced to a level such that the film is not cured. That is, a step of curing the film 2 for the backside of a semiconductor such as a thermal curing step or a photopolymerization step is not included before the step 3. For this reason, the manufacturing steps can be simplified, and a semiconductor device can be effectively manufactured.

### (4) Step 4

The method of manufacturing a semiconductor device of the present invention preferably has a step 4.

In the step 4, the semiconductor element 13 that is sealed in the step 3 is mounted to the adherend 6. Specifically, the carrier 11 in which the semiconductor element 13 is sealed in the step 3 is set in an electronic parts mounting machine and, the semiconductor element 13 is picked up from the pocket 12, and it is mounted to the adherend 6. The electronic part mounting machine is not especially limited, and a conventionally known machine can be used.

As shown in FIG. 5, the semiconductor element 13 that is picked up can be fixed to the adherend 6 such as a substrate with a flip-chip bonding method (a flip-chip mounting method). Specifically, the semiconductor chip 5 is fixed to an adherend 6 by a normal method in a form that the circuit surface (also referred to as the surface, a circuit pattern forming surface, or an electrode forming surface) of the semiconductor chip 5 faces the adherend 6. The semiconductor chip 5 can be fixed to the adherend 6 while securing electrical conduction of the semiconductor chip 5 with the adherend 6 by contacting and pressing a bump 51 formed on the circuit surface side of the semiconductor chip 5 to a conductive material 61 such as solder for bonding that is adhered to a connection pad of the adherend 6 and melting the conductive material 61 (a flip-chip bonding step). At this time, a space is formed between the semiconductor chip 5 and the adherend 6, and the distance of the space is generally about 30 μm to 300 μm. After flip-chip bonding (flip-chip connection) of the semiconductor chip 5 onto the adherend 6, it is important to wash the facing surface and the space between the semiconductor chip 5 to the adherend 6 and to seal the space by filling the space with a sealing material such as a sealing resin.

Various substrates such as a lead frame and a circuit board (a wiring circuit board, for example) can be used as the adherend 6. The material of the substrate is not especially limited, and examples thereof include a ceramic substrate and a plastic substrate. Examples of the plastic substrate include an epoxy substrate, a bismaleimide triazine substrate, and a polyimide substrate.

The material of the bump 51 and the conductive material 61 in the flip-chip bonding step are not especially limited, and examples thereof include solders (alloys) of a tin-lead metal material, a tin-silver metal material, a tin-silver-copper metal material, a tin-zinc metal material, and a tin-zinc-bismuth metal material, a gold metal material, and a copper metal material.

In the flip-chip bonding step, the bump 51 of the circuit surface side of the semiconductor chip 5 and the conductive material 61 on the surface of the adherend 6 are connected by melting the conductive material 61. The temperature when the conductive material 61 is molten is normally about 260° C. (250° C. to 300° C., for example).

In this step, the facing surface (an electrode forming surface) and the space between the semiconductor chip 5 and the adherend 6 are preferably washed. The washing liquid that is used in washing is not especially limited, and examples thereof include an organic washing liquid and a water washing liquid.

Next, a sealing step is performed to seal the space between the flip-chip bonded semiconductor chip 5 and the adherend 6. The sealing step is performed using a sealing resin. The sealing condition is not especially limited. Thermal curing of the sealing resin is performed normally by heating the sealing resin at 175° C. for 60 seconds to 90 seconds. However, the present invention is not limited to this, and curing can be performed at 165° C. to 185° C. for a few minutes, for example. When the film 2 for the backside of a semiconductor that can be used in the present invention is formed of a resin composition containing a thermosetting resin, not only a sealing resin, but also the uncured film 2 for the backside of a semiconductor can be also thermally cured at the same time in the heat treatment of the step. The film 2 for the backside of a semiconductor can be completely cured or almost completely cured by performing this step, and the film 2 for the backside of a semiconductor can be pasted to the backside of the semiconductor element 13 with excellent adhesion. Because the film 2 for the backside of a semiconductor can be thermally cured together with a sealing material in the sealing step, there is no necessity to newly add a step of thermally curing the film 2 for the backside of a semiconductor, the manufacturing steps can be simplified, and a semiconductor device can be effectively manufactured.

The sealing resin is not especially limited as long as it is a resin having insulation properties, and can be appropriately selected from sealing materials such as a known sealing resin. However, an insulating resin having elasticity is preferable. Examples of the sealing resin include a resin composition containing an epoxy resin. Examples of the epoxy resin include epoxy resins described above. The sealing resin with a resin composition containing an epoxy resin may contain a thermosetting resin such as a phenol resin other than the epoxy resin, a thermoplastic resin, and the like as a resin component besides the epoxy resin. The phenol resin can also be used as a curing agent for the epoxy resin, and examples of the phenol resin include the above-described phenol resins.

Various information such as character information and graphic information of the semiconductor device that is obtained with the above-described manufacturing method can be visibly recognized well.

the semiconductor device can be suitably used as various electronic apparatuses and electronic parts or materials and members thereof. Specific examples of the electronic apparatus in which the flip-chip mounted semiconductor device of the present invention can be used include a portable phone, PHS, a small computer such as PDA (personal digital assistant), a notebook personal computer, Netbook (trademark), or a wearable computer, a small electronic apparatus in which a portable phone and a computer are integrated, Digital Camera (trademark), a digital video camera, a small television, a small game machine, a small digital audio player, an electronic organizer, an electronic dictionary, an electronic apparatus terminal for an electronic book, and a mobile electronic apparatus (portable electronic apparatus) such as a small digital type clock or watch. Examples of the electronic apparatus also include an electronic apparatus other than a mobile type apparatus (i.e., a stationary apparatus) such as a desktop personal computer, a flat-panel television, an electronic apparatus for recording and playing such as a hard disc recorder or a DVD player, a projector, or a micromachine. Examples of the electronic parts or materials and members of the electronic apparatus and electronic parts include a component of CPU and components of various recording apparatuses such as a memory and a hard disk.

### EXAMPLES

The preferred examples of the present invention are illustratively explained in detail below. However, the purport of the present invention is not limited only to the materials, the compounding amount, etc. described in the examples as long as there is no restrictive description in particular. “Parts” described below means “parts by weight”.

### Example 1

### Production of Film for the Backside of Semiconductor

12 parts of an epoxy resin (trade name: “Epikote 1004” manufactured by Japan Epoxy Resins Co., Ltd.), 13 parts of a phenol resin (trade name: “Milex XLC-4L” manufactured by Mitsui Chemicals, Inc.), 92 parts of spherical silica (trade name: “SO-25R” manufactured by Admatechs Co., Ltd.), 2 parts of a dye 1 (trade name: “OIL GREEN 502” manufactured by Orient Chemical Industries Co., Ltd.), and 2 parts of a dye 2 (trade name: “OIL BLACK BS” manufactured by Orient Chemical Industries Co., Ltd.) to 100 parts of an acrylic ester polymer (trade name: “Paracron W-197CM” manufactured by Negami Chemical Industrial Co., Ltd.) having ethylacrylate-methylmethacrylate as a main component were dissolved in methylethylketone to prepare a solution of an adhesive composition having a solid content concentration of 23.6% by weight.

The solution of the adhesive composition was applied onto a release-treated film made of a silicone release-treated polyethylene terephthalate film having a thickness of 50 μm as a release liner (a separator) and dried at 130° C. for 2 minutes to produce a film A for the backside of a semiconductor having a thickness of 20 μm.

### <Production of Dicing-Tape Integrated Film for the Backside of Semiconductor>

The film A for the backside of a semiconductor was pasted onto a pressure-sensitive adhesive layer of a dicing tape (trade name: “V-8-T” manufactured by NITTO DENKO CORPORATION) using a hand roller to produce a dicing-tape integrated film for the backside of a semiconductor.

### <Grinding, Pasting, and Dicing of Semiconductor Wafer>

The backside of a semiconductor wafer (a silicon mirror wafer having a diameter of 8 inches and a thickness of 0.6 mm) was ground to a thickness of 0.2 mm. The dicing-tape integrated film for the backside of a semiconductor was peeled off from the separator, and the semiconductor wafer was pasted onto the film A for the backside of a semiconductor by roll pressing at 70° C. Then, dicing of the semiconductor wafer was performed. The dicing was performed in full-cut to obtain 10 mm square chips. The grinding conditions, pasting conditions, and dicing conditions of the semiconductor wafer were as follows.

### [Grinding Conditions of Semiconductor Wafer]

Grinding apparatus: trade name “DFG-8560” manufactured by DISCO Corporation

Semiconductor wafer: 8 inch diameter (backside grinding from a thickness of 0.6 mm to 0.2 mm)

### [Pasting Conditions]

Pasting apparatus: trade name “MA-3000III” manufactured by Nitto Seiki Co., Ltd.

Pasting speed: 10 mm/min

Pasting pressure: 0.15 MPa

Stage temperature at pasting: 70° C.

### [Dicing Conditions]

Dicing apparatus: trade name “DFD-6361” manufactured by DISCO Corporation

Dicing ring: “2-8-1” manufactured by DISCO Corporation

Dicing speed: 30 mm/sec

Dicing blades:
Z1; “2030-SE 27HCDD” manufactured by DISCO Corporation
Z2; “2030-SE 27HCBB” manufactured by DISCO Corporation

### Rotation of Dicing Blades:

Z1; 40,000 rpm
Z2; 45,000 rpm

Cutting method: Step cut

Wafer chip size: 10.0 mm square

### <Insertion and Marking of Semiconductor Element>

The semiconductor element (a semiconductor chip having the film. A for the backside of a semiconductor wafer) that was obtained by dicing was picked up. While a carrier was sent to a reel for winding up using a taping apparatus, the picked-up semiconductor element was inserted in a pocket, and a laser marking was performed on the film A for the backside of a semiconductor of the semiconductor element.

The taping apparatus that was used was as follows.

Taping apparatus: K8-d manufactured by DPE

The pickup conditions and the laser marking conditions were as follows.

### [Pickup Conditions]

Pickup apparatus: trade name: “SPA-300” manufactured by Shinkawa Ltd.

Number of pickup needles: 9 needles

Needle push-up speed: 20 mm/s

Needle push-up amount: 500 μm

Pickup time: 1 second

Expansion amount of dicing tape: 3 mm

### [Laser Marking Conditions]

Laser marking apparatus: trade name “MD-59900” manufactured by KEYENCE CORPORATION

Wavelength: 532 nm

Intensity: 1.0 W

Scan speed: 700 mm/sec

Q-switch frequency: 64 kHz

A two-dimensional code having an entire size of about 4 mm×about 4 mm and a size of each cell of 0.08 mm×0.24 mm was marked.

From Example 1, it was made clear that a semiconductor device could be manufactured effectively by marking the semiconductor element that is inserted in a pocket of the carrier that can be wound up in a reel state. In addition, characters that were formed by marking were able to be read well.

### DESCRIPTION OF THE REFERENCE NUMERALS

1 Dicing-tape integrated film for the backside of a semiconductor
2 Film for the backside of a semiconductor
3 Dicing tape
4 Semiconductor wafer
5 Semiconductor chip
6 Adherend
11 Carrier that can be wound up in a reel state
12 Pocket
13 Semiconductor element
14 Sending direction
31 Base
32 Pressure-sensitive adhesive layer
33 Portion that corresponds to a pasting portion of a semiconductor wafer
51 Bump formed on the circuit surface side of the semiconductor chip 5
61 Conductive material for bonding that is adhered to a connection pad of the adherend 6

1. A method of marking a semiconductor element, wherein marking is performed on a semiconductor element that is inserted in a pocket of a carrier that can be wound up in a reel state.

2. The method of marking a semiconductor element according to claim 1, wherein the marking is laser marking.

3. The method of marking a semiconductor element according to claim 1, wherein the marking is performed on the backside of the semiconductor element.

4. The method of marking a semiconductor element according to claim 1, wherein the semiconductor element has a film for the backside of a flip-chip semiconductor that is formed on the backside of a semiconductor chip that is flip-chip-connected to an adherend, and
marking is performed on the film for the backside of a flip-chip semiconductor.

5. A method of manufacturing a semiconductor device comprising:
a step 1 of inserting a semiconductor element in a pocket of a carrier that can be wound up in a reel state; and
a step 2 of marking the semiconductor element that is inserted in the pocket.

6. The method of manufacturing a semiconductor device according to claim 5, which comprises:
a step A of laminating a dicing-tape integrated film for the backside of a semiconductor, in which the film for the backside of a flip-chip semiconductor that is formed on the backside of a semiconductor chip that is flip-chip-connected to an adherend is laminated onto a dicing tape, to a semiconductor wafer;
a step B of dicing the semiconductor wafer that is laminated by the film for the backside of a flip-chip semiconductor; and
a step C of picking up the semiconductor chip obtained by dicing together with the film for the backside of a flip-chip semiconductor to obtain the semiconductor element having the film for the backside of a flip-chip semiconductor, wherein
marking is performed in the step 2 on the film for the backside of a flip-chip semiconductor of the semiconductor element that is obtained in the step C.

7. The method of manufacturing a semiconductor device according to claim 5, which comprises a step 3 of sealing the semiconductor element that is marked in the step 2 by pasting a cover tape to the carrier that can be wound up in a reel state.

8. The method of manufacturing a semiconductor device according to claim 5, wherein the semiconductor element has a film for the backside of a flip-chip semiconductor that is formed on the backside of a semiconductor chip that is flip-chip-connected to an adherend, and
the film for the backside of a flip-chip semiconductor is formed of a resin composition containing a thermoplastic resin and/or a thermosetting resin.

9. The method of manufacturing a semiconductor device according to claim 8, wherein the film for the backside of a flip-chip semiconductor is formed of the resin composition containing a thermosetting resin, and
the thermosetting resin is uncured in the step 3.

10. A semiconductor device obtained with the manufacturing method according to claim 5.
